(19) United States
(12) Patent Application Publication
(10) Pub. No.: US 2025/0113502 A1
(43) Pub. Date: Apr. 3, 2025

(54) Method for Integration of Tantalum Nitride Resistive Heater for Photonics Devices and Related Structure

(71) Applicant: Newport Fab, LLC dba Tower Semiconductor Newport Beach, Newport Beach, CA (US)

(72) Inventors: Zhirong Tang, Lake Oswego, OR (US); Oleg Martynov, Lebanon, NH (US); Edward Preisler, San Clemente, CA (US)

(21) Appl. No.: 18/939,988

(22) Filed: Nov. 7, 2024

Related U.S. Application Data
(63) Continuation-in-part of application No. 17/967,159, filed on Oct. 17, 2022.
(63) Continuation-in-part of application No. 17/975,090, filed on Oct. 27, 2022.

(51) Int. Cl. G02F 1/21; G02F 1/225; H01L 23/522

(52) U.S. Cl. CPC H10D 1/474; G02F 1/212; G02F 1/225; H01L 23/5228

(57) ABSTRACT

In fabricating a semiconductor structure, a substrate is provided. A thermally-tunable photonics device is formed. A tantalum nitride (TaN) layer is formed over the substrate. A capping dielectric layer is formed over the TaN layer. The capping dielectric layer is etched to form a capping dielectric segment. A TaN resistive heater is formed from the TaN layer. The TaN resistive heater is proximate to and configured to tune the thermally-tunable photonics device.

### CLAIMS OF PRIORITY

The present application is a continuation-in-part of and claims the benefit of and priority to application Ser. No. 17/967,159 filed on Oct. 17, 2022, titled “Tantalum Nitride Resistive Heater for Thermally-Tunable Photonics Devices.” The present application is also a continuation-in-part of and claims the benefit of and priority to application Ser. No. 17/975,090 filed on Oct. 27, 2022, titled “Integration of Optoelectronic Devices Comprising Lithium Niobate or Other Pockels Materials.” The entire content of the above-identified applications is hereby incorporated fully by reference into the present application.

### BACKGROUND

Photonics devices are commonly utilized in data communications and other fields. Various applications of photonics devices, such as interferometers, phase shifters, and optical switches, can utilize a thermo-optical effect to affect changes in optical properties (such as phase, amplitude, wavelength, etc.). In one approach, a heater is introduced to trigger the desired thermo-optical effect in the photonics device.

However, conventional heater designs have relatively high temperature coefficients. When on, their temperature increases, and they experience greater changes in resistance due to the high temperature coefficients. In turn, a driving circuit needs to make greater adjustments in supplied power, making it more difficult to maintain the conventional heater at a constant temperature. In order to accurately tune the desired thermo-optical effect in the photonics device, complex driving circuitry and relatively high power consumption are sometimes required.

Thus, there is a need in the art for a semiconductor structure that can efficiently tune a thermally-tunable photonics device.

### SUMMARY

The present disclosure is directed to method for integration of tantalum nitride resistive heater for photonics devices and related structure, substantially as shown in and/or described in connection with at least one of the figures, and as set forth in the claims.

### BRIEF DESCRIPTION OF THE DRAWINGS

FIG. 1A illustrates a portion of a flowchart of an exemplary method for manufacturing a semiconductor structure according to one implementation of the present application.

FIG. 1B illustrates a portion of a flowchart of an exemplary method for manufacturing a semiconductor structure, as a continuation to the flowchart of FIG. 1A, according to one implementation of the present application.

FIG. 2 illustrates a cross-sectional view of a portion of a semiconductor structure processed in accordance with the flowchart of FIG. 1A according to one implementation of the present application.

FIG. 3A illustrates a cross-sectional view of a portion of a semiconductor structure processed in accordance with the flowchart of FIG. 1A according to one implementation of the present application.

FIG. 3B illustrates a layout of a portion of a semiconductor structure corresponding to FIG. 3A processed in accordance with the flowchart of FIG. 1A according to one implementation of the present application.

FIG. 4 illustrates a cross-sectional view of a portion of a semiconductor structure processed in accordance with the flowchart of FIG. 1A according to one implementation of the present application.

FIG. 5 illustrates a cross-sectional view of a portion of a semiconductor structure processed in accordance with the flowchart of FIG. 1A according to one implementation of the present application.

FIG. 6 illustrates a cross-sectional view of a portion of a semiconductor structure processed in accordance with the flowchart of FIG. 1A according to one implementation of the present application.

FIG. 7 illustrates a cross-sectional view of a portion of a semiconductor structure processed in accordance with the flowchart of FIG. 1A according to one implementation of the present application.

FIG. 8A illustrates a cross-sectional view of a portion of a semiconductor structure processed in accordance with the flowchart of FIG. 1A according to one implementation of the present application.

FIG. 8B illustrates a layout of a portion of a semiconductor structure corresponding to FIG. 8A processed in accordance with the flowchart of FIG. 1A according to one implementation of the present application.

FIG. 9 illustrates a cross-sectional view of a portion of a semiconductor structure processed in accordance with the flowchart of FIG. 1B according to one implementation of the present application.

FIG. 10 illustrates a cross-sectional view of a portion of a semiconductor structure processed in accordance with the flowchart of FIG. 1B according to one implementation of the present application.

FIG. 11 illustrates a cross-sectional view of a portion of a semiconductor structure processed in accordance with the flowchart of FIG. 1B according to one implementation of the present application.

FIG. 12 illustrates a cross-sectional view of a portion of a semiconductor structure processed in accordance with the flowchart of FIG. 1B according to one implementation of the present application.

FIG. 13 illustrates a cross-sectional view of a portion of a semiconductor structure processed in accordance with the flowchart of FIG. 1B according to one implementation of the present application.

FIG. 14 illustrates a cross-sectional view of a portion of a semiconductor structure processed in accordance with the flowchart of FIG. 1B according to one implementation of the present application.

FIG. 15 illustrates an exemplary graph of output intensity versus wavelength according to one implementation of the present application.

FIG. 16 illustrates an exemplary graph of phase shift versus heater power according to one implementation of the present application.

FIG. 17A illustrates a cross-sectional view of a portion of a semiconductor structure according to an alternative implementation of the present application.

FIG. 17B illustrates a layout of a portion of a semiconductor structure corresponding to FIG. 17A according to an alternative implementation of the present application.

FIG. 17C illustrates a cross-sectional view of a portion of a semiconductor structure corresponding to FIG. 17B according to an alternative implementation of the present application.

FIG. 18 illustrates a cross-sectional view of a portion of a semiconductor structure according to an alternative implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions. As used herein, “over” may refer to directly or indirectly over.

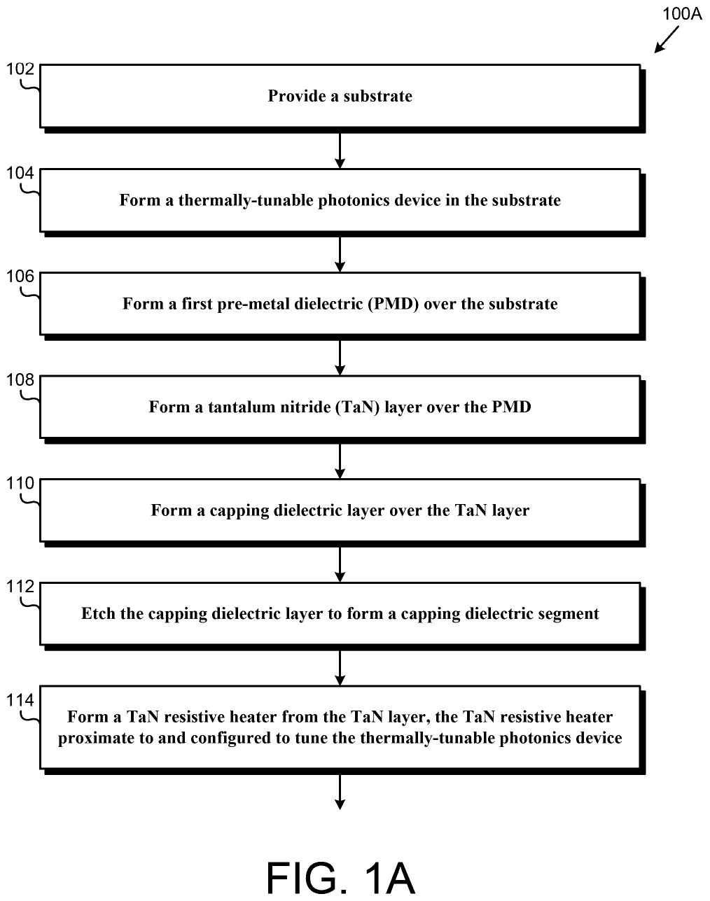

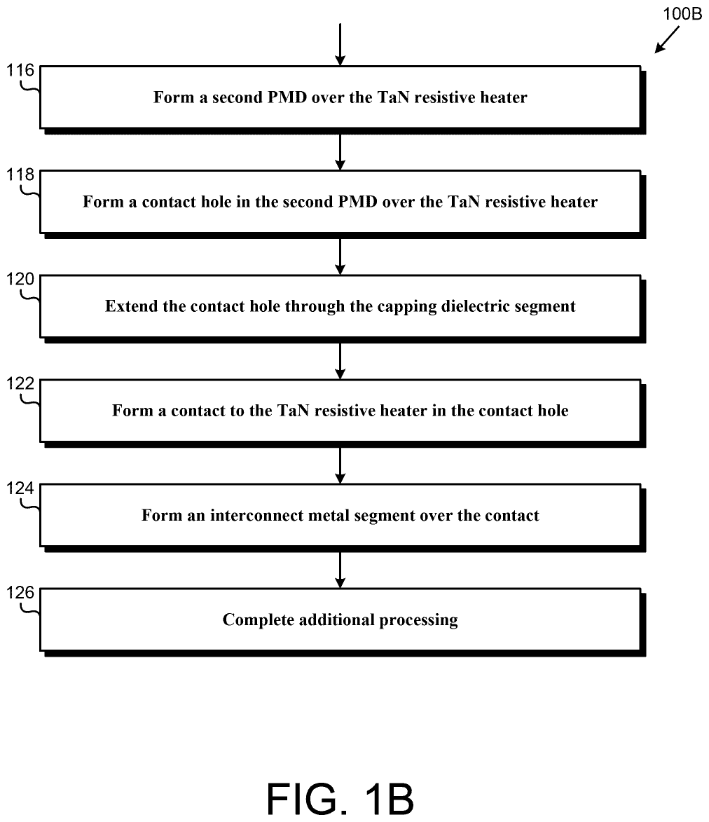

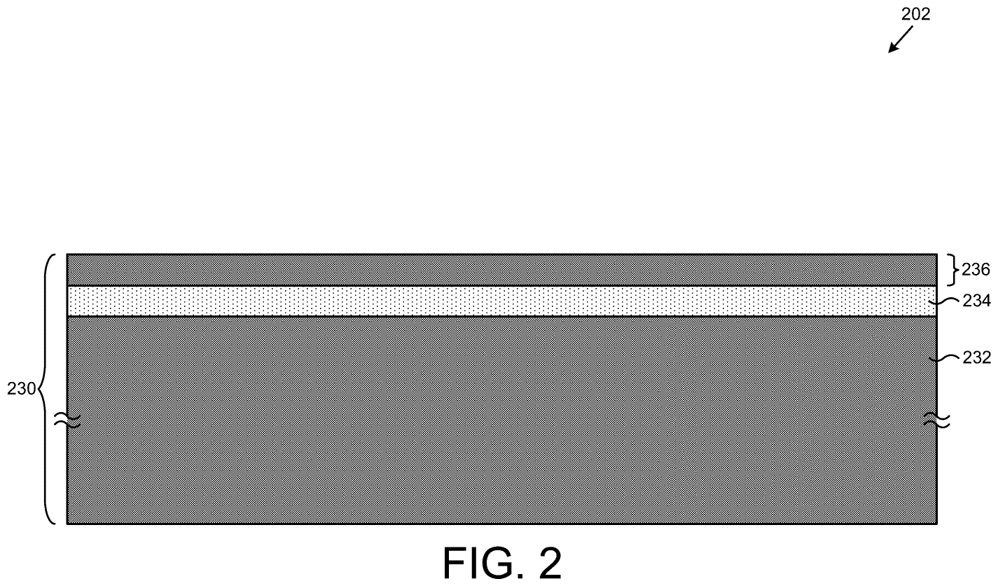

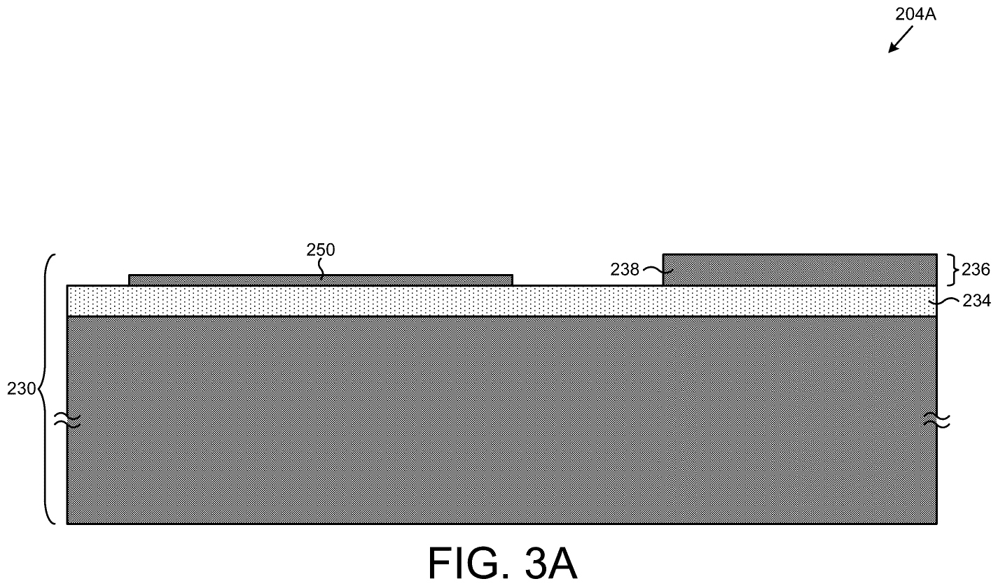

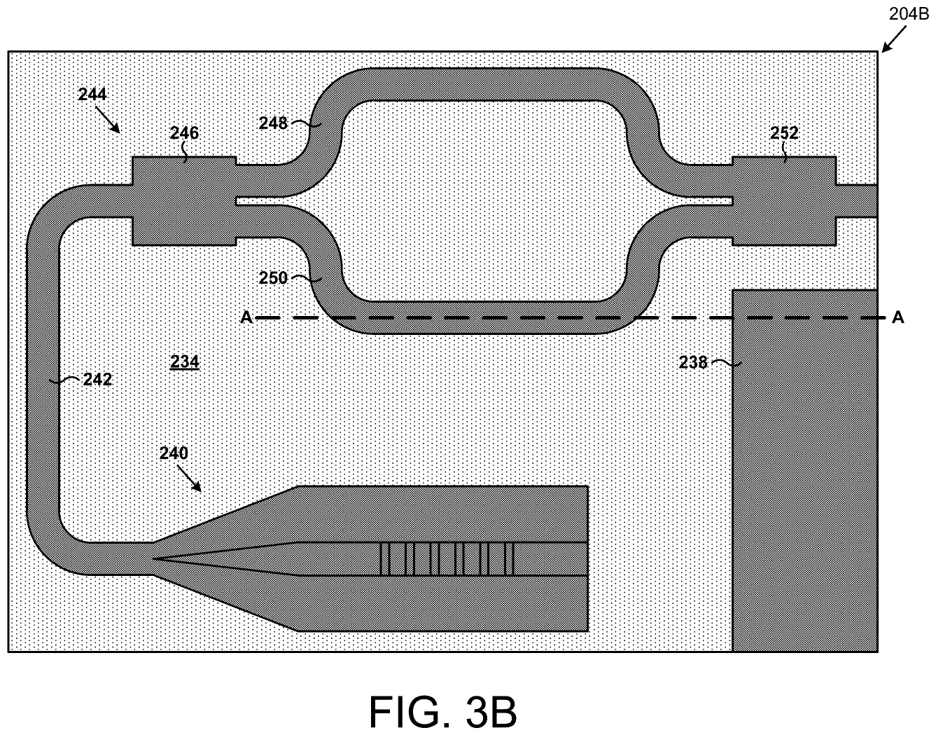

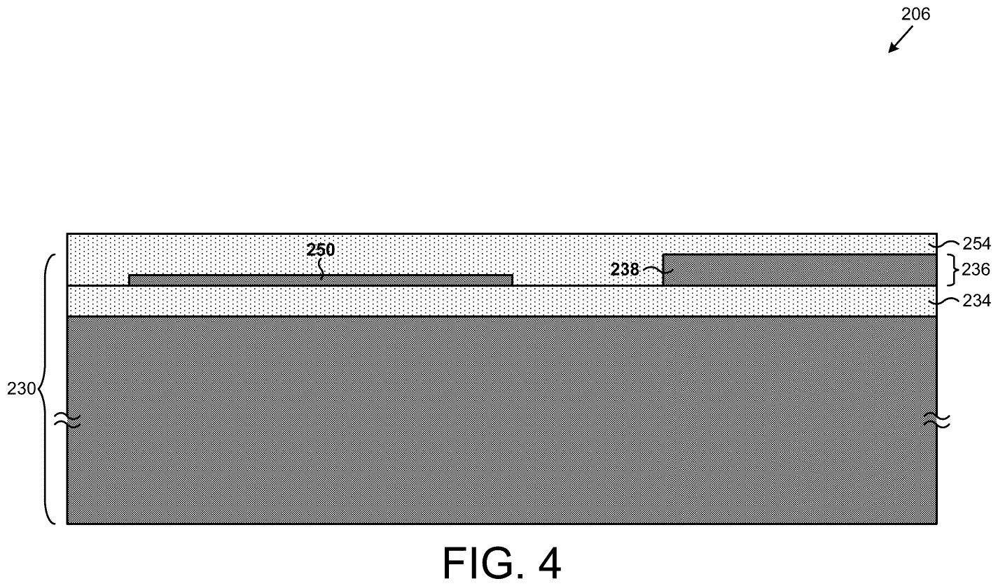

FIG. 1A illustrates a portion of a flowchart of an exemplary method for manufacturing a semiconductor structure according to one implementation of the present application. Structures shown in FIGS. 2 through 8 illustrate the results of performing actions 102 through 114 shown in flowchart 100A of FIG. 1A. For example, FIG. 2 shows a semiconductor structure after performing action 102 in FIG. 1A, FIG. 3A shows a semiconductor structure after performing action 104 in FIG. 1A, FIG. 4 shows a semiconductor structure after performing action 106 in FIG. 1A, and so forth.

FIG. 1B illustrates a portion of a flowchart of an exemplary method for manufacturing a semiconductor structure, as a continuation to flowchart 100A of FIG. 1A, according to one implementation of the present application. Structures shown in

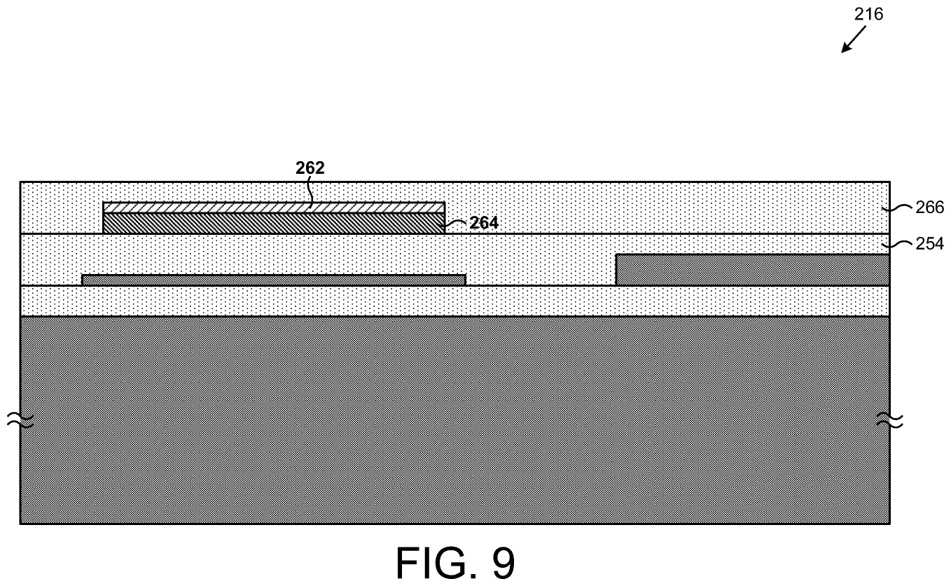

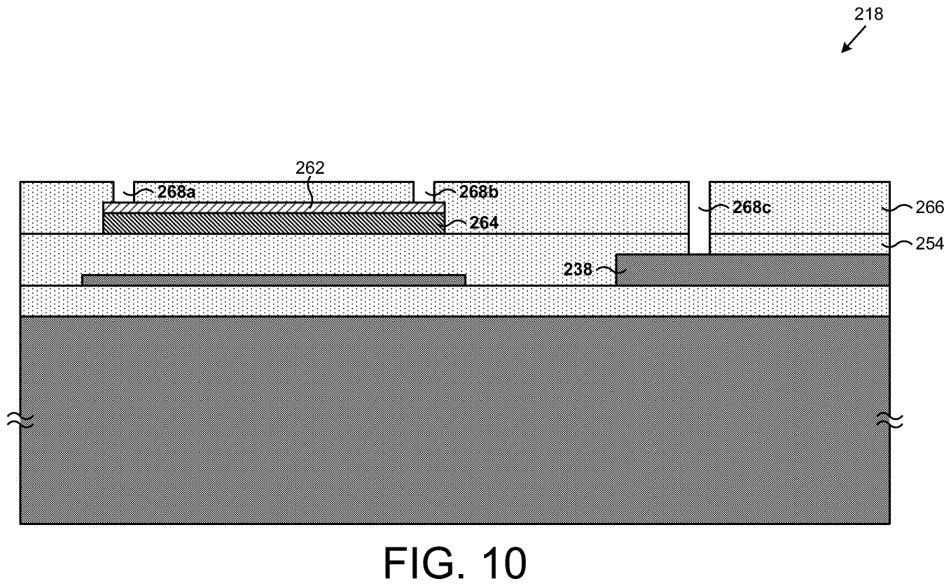

FIGS. 9 through 14 illustrate the results of performing actions 116 through 126 shown in flowchart 100B of FIG. 1B. For example, FIG. 9 shows a semiconductor structure after performing action 116 in FIG. 1B, FIG. 10 shows a semiconductor structure after performing action 118 in FIG. 1B, and so forth.

Actions 102 through 126 shown in flowcharts 100A and 100B of FIGS. 1A and 1B are sufficient to describe one implementation of the present inventive concepts. Other implementations of the present inventive concepts may utilize actions different from those shown in flowcharts 100A and 100B of FIGS. 1A and 1B. Certain details and features have been left out of the flowcharts that are apparent to a person of ordinary skill in the art. For example, an action may consist of one or more sub-actions or may involve specialized equipment or materials, as known in the art. Moreover, some actions, such as masking and cleaning actions, may be omitted so as not to distract from the illustrated actions.

FIG. 2 illustrates a cross-sectional view of a portion of a semiconductor structure processed in accordance with action 102 in flowchart 100A of FIG. 1A according to one implementation of the present application. As shown in FIG. 2, in semiconductor structure 202, substrate 230 is provided.

Semiconductor structure 202 includes substrate 230 having handle wafer 232, buried oxide (BOX) 234, and semiconductor layer 236. In the present implementation, substrate 230 is a semiconductor-on-insulator (SOI) substrate. In providing substrate 230, a bonded and etch back SOI (BESOI) process can be used, as known in the art. Alternatively, as also known in the art, a SIMOX process or a “smart cut” process can also be used for providing substrate 230. In various implementations, substrate 230 may be another type of substrate other than an SOI substrate.

In one implementation, handle wafer 232 is undoped bulk silicon. In various implementations, handle wafer 232 can comprise germanium, group III-V material, or any other suitable handle material. In various implementations, handle wafer 232 has a thickness of approximately seven hundred microns (700 μm) or greater or less. In one implementation, a trap rich layer can be situated between handle wafer 232 and BOX 234. In various implementations, BOX 234 typically comprises silicon dioxide (SiO₂), but it may also comprise silicon nitride (Si_{X}N_{Y}), or another insulator material. In various implementations, BOX 234 has a thickness of approximately one micron (1 μm) to approximately three microns (3 μm) or greater or less. In one implementation, semiconductor layer 236 includes monocrystalline silicon. In various implementations, semiconductor layer 236 can comprise germanium, group III-V material, or any other semiconductor material. In various implementations, semiconductor layer 236 has a thickness of approximately three hundred nanometers (200 nm) to approximately five hundred nanometers (500 nm) or greater or less.

In one implementation, substrate 230 is a group IV substrate. As used herein, the phrase “group IV” refers to a semiconductor material that includes at least one group IV element such as silicon (Si), germanium (Ge), and carbon (C), and may also include compound semiconductors such as silicon germanium (SiGe) and silicon carbide (SiC), for example. “Group IV” also refers to semiconductor materials that include more than one layer of group IV elements, or doping of group IV elements to produce strained group IV materials, and may also include group IV based composite substrates such as silicon on insulator substrates, separation by implantation of oxygen (SIMOX) process substrates, and silicon on sapphire (SOS) substrates, for example. In one implementation, substrate 230 is a semiconductor-on-insulator (SOI) wafer having a diameter of approximately two hundred millimeters (200 mm). In various implementations, substrate 230 can be glass, quartz, or sapphire.

FIG. 3A illustrates a cross-sectional view of a portion of a semiconductor structure processed in accordance with action 104 in flowchart 100A of FIG. 1A according to one implementation of the present application. As shown in FIG. 3A, in semiconductor structure 204A, thermally-tunable photonics device 250 is formed in substrate 230.

Semiconductor layer 236 includes device 238 and thermally-tunable photonics device 250 on BOX 234. In semiconductor structure 202, thermally-tunable photonics device 250 is formed by patterning semiconductor layer 236. Parts of semiconductor layer 236 are removed to isolate thermally-tunable photonics device 250 from the rest of semiconductor layer 236 and device 238. In other implementations, dedicated isolation structures can be used. Thermally-tunable photonics device 250 is any type of photonics device that experiences a thermo-optical effect. That is, thermally-tunable photonics device 250 is any type of photonics device capable of varying an optical property (such as phase, amplitude, wavelength, etc.) in response to changes in temperature. In various implementations, thermally-tunable photonics device 250 can be an interferometer, a phase shifter, a waveguide, or an optical switch.

Device 238 can be any electronic device. In various implementations, device 238 can be a transistor, an operational amplifier, a driver, a filter, a mixer, or a diode. Device 238 can be formed, for example, by patterning, doping, and/or performing other processing on semiconductor layer 236 of substrate 230. In various implementations, device 238 can be an active circuit comprising multiple active devices, or comprising passive devices in combination with at least one active device. Other devices (not shown in FIG. 3A) can also be integrated in substrate 230. For example, additional electronic or photonic devices can be situated in semiconductor layer 236.

In various implementations, thermally-tunable photonics devices can be situated over substrate 230, instead of (or in addition to) in substrate 230. For example, substrate 230 can be a quartz substrate and thermally-tunable photonics device 250 can be a silicon nitride waveguide situated over substrate 230. As another example, substrate 230 can be a glass substrate and thermally-tunable photonics device 250 can be a waveguide comprising Pockels material situated over substrate 230. In various implementations, Pockels material can comprise lithium niobate (LiNbO₃), lithium tantalate (LiTa), potassium dihydrogen phosphate (KDP), deuterated potassium dihydrogen phosphate (DKDP), rubidium titanyl phosphate (RTP), potassium titanyl phosphate (KTP), potassium titanyl arsenate (KTA), barium borate (BBO), barium titanate (BTO), ammonium dihydrogen phosphate (ADP), cadmium telluride (CdTe), organic materials which demonstrate a strong Pockels effect, or any other suitable Pockels material.

FIG. 3B illustrates a layout of a portion of a semiconductor structure corresponding to FIG. 3A processed in accordance with action 104 in flowchart 100A of FIG. 1A according to one implementation of the present application. FIG. 3A represents an exemplary cross-section along line “A” in FIG. 3B. As shown in FIG. 3B, in semiconductor structure 204, thermally-tunable photonics device 250 is formed.

Semiconductor structure 204 includes device 238 and photonics devices 240, 242, 244, 246, 248, 250, and 252. In the present implementation, device 238 and photonics devices 240, 242, 244, 246, 248, 250, and 252 are formed in substrate 230 (shown in FIG. 3A) by patterning semiconductor layer 236 (shown in FIG. 3A). Portions of semiconductor layer 236 are also removed to isolate devices, exposing portions of BOX 234. In other implementations, dedicated isolation structures can be used.

In the present implementation, photonics device 244 is a thermally tunable Mach-Zender interferometer and includes input splitter 246, waveguide arms 248 and 250, and output combiner 252. Light passes through input splitter 246, propagates in arms 248 and 250, and is then recombined in a single waveguide at output combiner 252. According to the phase difference between the two arms 248 and 250, the signals will interfere differently depending on the wavelength of the light, leading to a change in the intensity of the output signal. In the present implementation, waveguide arms 248 and 250 have the same lengths and photonics device 244 is a symmetric interferometer. In another implementation, photonics device 244 can be an asymmetric interferometer. In various implementations, photonics device 244 can be a Michelson interferometer, a grating coupler, a reflector, or any other types of photonics devices that experience the thermo-optical effect described below.

In the present implementation, photonics devices 240 and 242 are a grating coupler and waveguide respectively. Photonics device 240 couples light into the plane shown in FIG. 3A, such that the light can be optically coupled to photonics device 244 through photonics device 242. Photonics devices 240 and 244 can be optically connected to additional devices (not shown in FIG. 3B) and/or to an optical output/input interface (not shown in FIG. 3B). It is noted that the optical coupling in FIG. 3B is bidirectional, and photonics device 244 can provide light received from photonics devices 252 to photonics device 240.

Photonics devices 240, 242, 244, 246, 248, 250, and 252 can have different dimensions and/or can include different structures than those shown in FIG. 3B. In various implementations, semiconductor structure 204B can include greater or fewer devices than shown, by way of example, in FIG. 3B. In various implementations, other devices (not shown in FIG. 3B), such as transistors, operational amplifiers, drivers, filters, mixers, diodes, active circuits, and/or passive devices, can be integrated in semiconductor structure 204B.

FIG. 4 illustrates a cross-sectional view of a portion of a semiconductor structure processed in accordance with action 106 in flowchart 100A of FIG. 1A according to one implementation of the present application. As shown in FIG. 4, in semiconductor structure 206, pre-metal dielectric (PMD) 254 is formed over substrate 230.

PMD 254 is situated over device 238 and thermally-tunable photonics device 250 in semiconductor layer 236 and over BOX 234. PMD 254 insulates device 238 and thermally-tunable photonics device 250, and aids subsequent processing. In various implementations, PMD 254 can comprise borophosphosilicate glass (BPSG), tetra-ethyl ortho-silicate (TEOS), SiO₂, Si_{X}N_{Y}, silicon oxynitride (Si_{X}O_{Y}N_{Z}), or another dielectric. PMD 254 can be formed by depositing and planarizing a dielectric layer, for example, using chemical mechanical polishing (CMP).

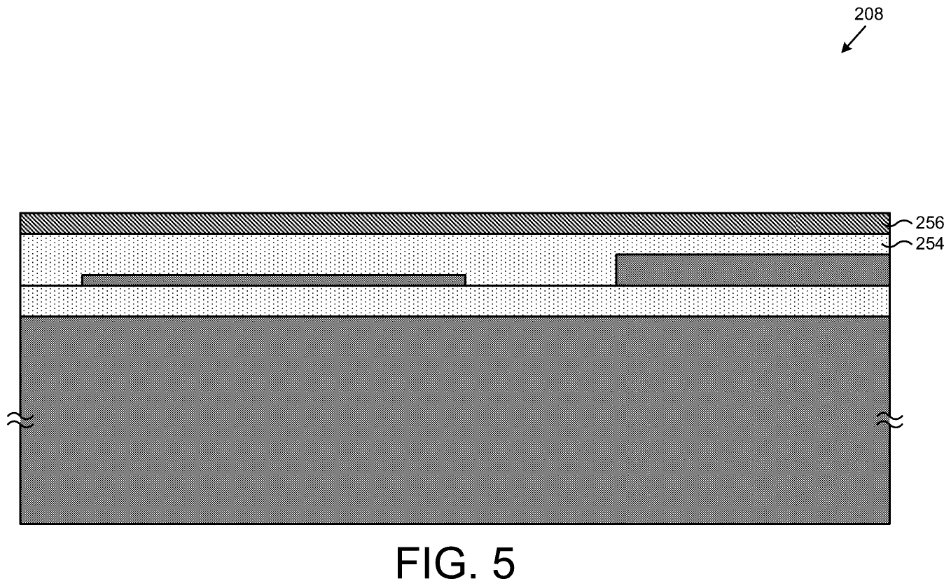

FIG. 5 illustrates a cross-sectional view of a portion of a semiconductor structure processed in accordance with action 108 in flowchart 100A of FIG. 1A according to one implementation of the present application. As shown in FIG. 5, in semiconductor structure 208, tantalum nitride (TaN) layer 256 is formed over PMD 254.

In the present implementation, TaN layer 256 is a thin film. In various implementations, TaN layer 256 has a thickness of between approximately one hundred angstroms (100 Å) and one thousand angstroms (1,000 Å). TaN layer 256 can be formed by depositing, for example, using chemical vapor deposition (CVD), plasma enhanced chemical vapor deposition (PECVD), or physical vapor deposition (PVD). TaN layer 256 can be also be formed using any metal thin film technique known in the art. By appropriately controlling the stoichiometry of TaN layer 256 (e.g., by appropriately selecting the ratio of tantalum to nitrogen), the temperature coefficient can be kept close to zero. In various implementations, TaN layer 256 has a temperature coefficient of approximately zero plus or minus approximately fifty parts per million per degree Centigrade (0±50 ppm/° C.).

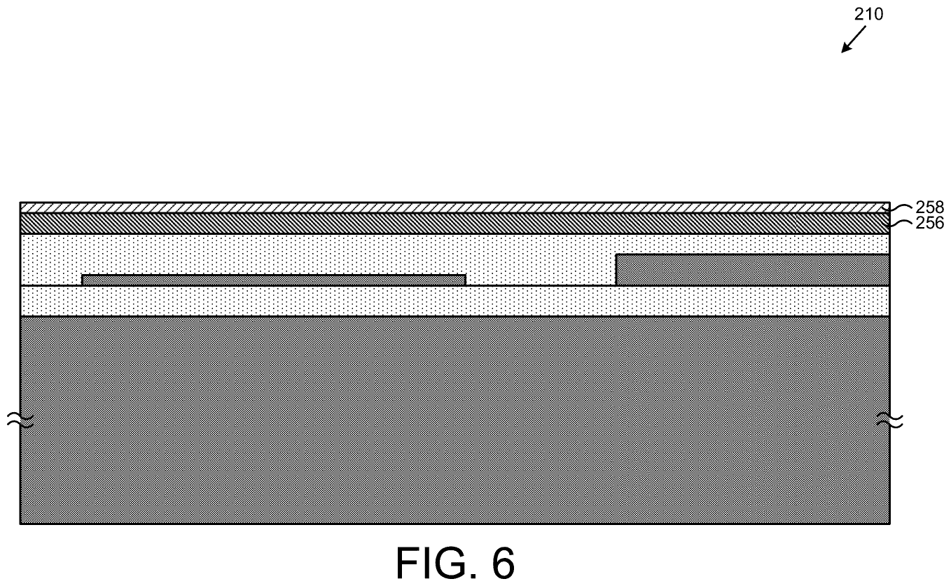

FIG. 6 illustrates a cross-sectional view of a portion of a semiconductor structure processed in accordance with action 110 in flowchart 100A of FIG. 1A according to one implementation of the present application. As shown in FIG. 6, in semiconductor structure 210, capping dielectric layer 258 is formed over TaN layer 256.

In one implementation, capping dielectric layer 258 can comprise a nitride, such as Si_{X}N_{Y} or Si_{X}O_{Y}N_{Z}. In other implementations capping dielectric layer 258 can comprise another dielectric. Capping dielectric layer 258 can be formed, for example, by PECVD or high density plasma CVD (HDP-CVD). In various implementations, a deposition thickness of capping dielectric layer 258 can be approximately fifty nanometers (50 nm) or greater or less.

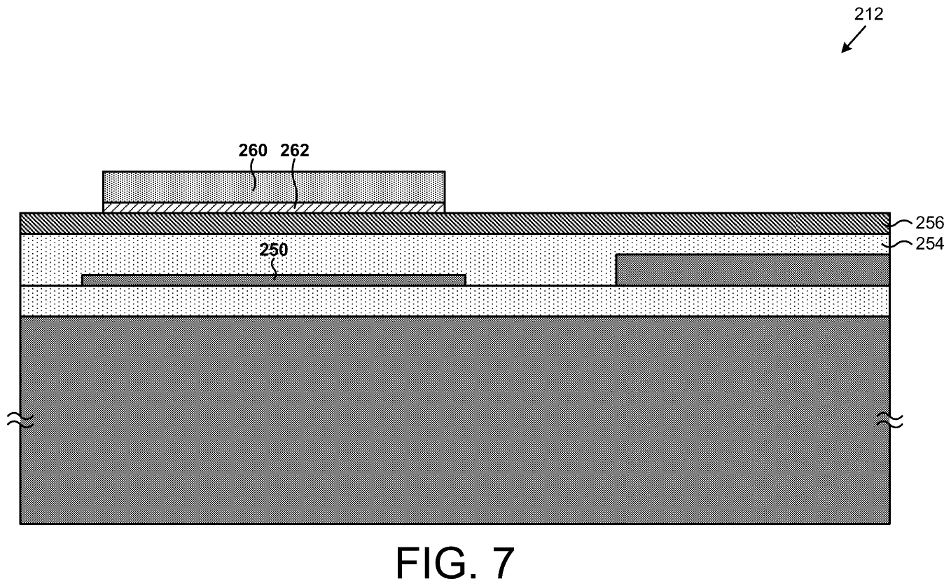

FIG. 7 illustrates a cross-sectional view of a portion of a semiconductor structure processed in accordance with action 112 in flowchart 100A of FIG. 1A according to one implementation of the present application. As shown in FIG. 7, in semiconductor structure 212, capping dielectric layer 258 (shown in FIG. 6) is etched to form capping dielectric segment 262.

Capping dielectric layer 258 can be etched using any technique known in the art. In one implementation, the etch is selective to capping dielectric layer 258 and stops on TaN layer 256. Photoresist segment 260 is utilized to protect capping dielectric segment 262 when capping dielectric layer 258 is etched. Photoresist segments 260 be formed by forming a photoresist layer, then selectively exposing the photoresist layer to light using a patterned mask, and then applying a developer to remove exposed portions. The photoresist layer be formed using any technique known in the art, such as spin coating. The photoresist layer can comprise any photoresist material known in the art, such as SU-8. After etching, capping dielectric segment 262 overlies thermally-tunable photonics device 250, with TaN layer 256 and PMD 254 between.

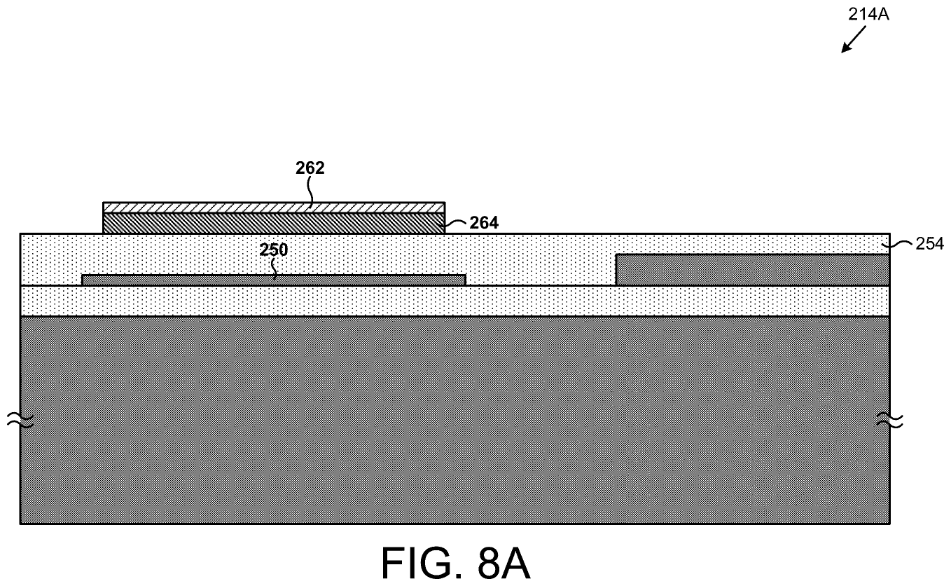

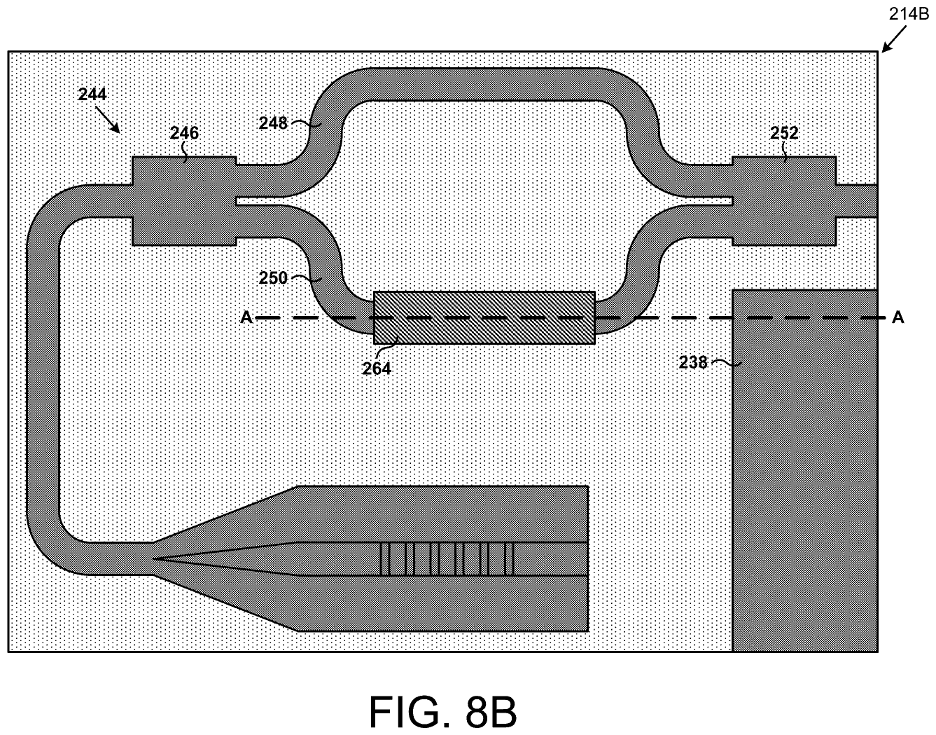

FIG. 8A illustrates a cross-sectional view of a portion of a semiconductor structure processed in accordance with action 114 in flowchart 100A of FIG. 1A according to one implementation of the present application. As shown in FIG. 8A, in semiconductor structure 214A, TaN resistive heater 264 is formed from TaN layer 256 (shown in FIG. 7).

TaN resistive heater 264 is situated on PMD 254. TaN resistive heater 264 is proximate to and configured to tune thermally-tunable photonics device 250. TaN resistive heater 264 generates heat via Joule heating. TaN resistive heater 264 can be electrically connected to a power source (not shown in FIG. 8) in subsequent actions. When TaN resistive heater 264 is supplied with power, it generates heat. When heat generated by TaN resistive heater 264 reaches thermally-tunable photonics device 250, the thermo-optical effect varies an optical property (such as phase, amplitude, wavelength, etc.) of thermally-tunable photonics device 250. In turn, optical properties of thermally-tunable photonics device 250 can be tuned through a range of values.

The position and orientation of TaN resistive heater 264 relative to thermally-tunable photonics device 250, can be chosen such that heat generated by TaN resistive heater 264 readily reaches thermally-tunable photonics device 250 and TaN resistive heater 264 is configured to tune thermally-tunable photonics device 250. In the present implementation, TaN resistive heater 264 overlies thermally-tunable photonics device 250. In one implementation, a length of TaN resistive heater 264 and a length of thermally-tunable photonics device 250 can be substantially parallel. In one implementation, a length of TaN resistive heater 264 can be substantially perpendicular to a portion of thermally-tunable photonics device 250 to be tuned.

The dimensions of TaN resistive heater 264 can also be chosen such that heat generated by TaN resistive heater 264 readily reaches thermally-tunable photonics device 250 and TaN resistive heater 264 is configured to tune thermally-tunable photonics device 250. In the present implementation, TaN resistive heater 264 is a thin film resistive heater. In various implementations, TaN resistive heater 264 has a thickness of between approximately one hundred angstroms (100 Å) and one thousand angstroms (1,000 Å). In various implementations, the thicknesses and materials of PMD 254 can be chosen to facilitate TaN resistive heater 264 tuning thermally-tunable photonics device 250.

TaN resistive heater 264 can be formed by patterning TaN layer 256 (shown in FIG. 7) using any technique known in the art, such as a chlorine-based plasma etch. In one implementation, the etch is selective to TaN layer 256 and stops on PMD 254. Capping dielectric segment 262 is utilized to protect TaN resistive heater 264 when TaN layer 256 is etched. Accordingly, capping dielectric segment 262 over TaN resistive heater 264 is substantially aligned with TaN resistive heater 264. That is, the boundaries of TaN resistive heater 264 generally mirror that of capping dielectric segment 262, except for normal sidewall tapering and other normal process variations associated with patterning metal, and except for any holes subsequently formed in capping dielectric segment 262 to contact TaN resistive heater 264.

FIG. 8B illustrates a layout of a portion of a semiconductor structure corresponding to FIG. 8A processed in accordance with action 114 in flowchart 100A of FIG. 1A according to one implementation of the present application. FIG. 8A represents an exemplary cross-section along line “A” in FIG. 8B. Various features, such as PMD 254 and capping dielectric segment 262, are seen through in the layout of FIG. 8B. As shown in FIG. 8B, in semiconductor structure 214B, TaN resistive heater 264 is formed.

TaN resistive heater 264 overlies and is configured to tune thermally-tunable photonics device 250. As described above, thermally-tunable photonics device 250 can be a waveguide arm of thermally tunable Mach-Zender interferometer 244. TaN resistive heater 264 can alter a thermo-optic property of waveguide arm 250 such that lights passing through waveguide arms 248 and 250 exhibit different behavior and interfere differently when combined at the interferometer output causing, for example, a shift in phase of the output signal.

In the present implementation, a length of TaN resistive heater 264 and a length of thermally-tunable photonics device 250 are substantially parallel. In one implementation, a length of TaN resistive heater 264 can be substantially perpendicular to a portion of thermally-tunable photonics device 250 to be tuned. In various implementations, TaN resistive heater 264 can be situated centrally with respect to multiple thermally-tunable photonics devices. Likewise, in various implementations, multiple TaN resistive heaters are situated proximate to thermally-tunable photonics device 250. TaN resistive heater 264 can have different dimensions than those shown in FIG. 8B. In the present implementation, TaN resistive heater 264 is substantially rectangular. In various implementations, TaN resistive heater 264 can have any other design, such spiral or serpentine.

FIG. 9 illustrates a cross-sectional view of a portion of a semiconductor structure processed in accordance with action 116 in flowchart 100B of FIG. 1B according to one implementation of the present application. As shown in FIG. 9, in semiconductor structure 216, PMD 266 is formed over TaN resistive heater 264.

In particular, PMD 266 is formed on capping dielectric segment 262 and PMD 254. PMD 266 can be formed in a similar manner to PMD 254, and may have any implementations described above. Notably, capping dielectric segment 262 was not removed after forming TaN resistive heater 264.

FIG. 10 illustrates a cross-sectional view of a portion of a semiconductor structure processed in accordance with action 118 in flowchart 100B of FIG. 1B according to one implementation of the present application. As shown in FIG. 10, in semiconductor structure 218, contact holes 268a and 268b are formed in PMD 266 over TaN resistive heater 264.

Contact holes 268a and 268b can be formed by etching PMD 266 using any technique known in the art. In one implementation, the etch is selective to PMD 266 and stops on capping dielectric segment 262. Contact hole 268c is also formed in PMDs 254 and 266 over device 238. In one implementation, an etch stop layer is situated over device 238. Although contact holes 268a, 268b, and 268c are shown to be formed concurrently in FIG. 10, in various implementations, contact hole 268c may be formed separately (i.e., before or after) contact holes 268a and 268b.

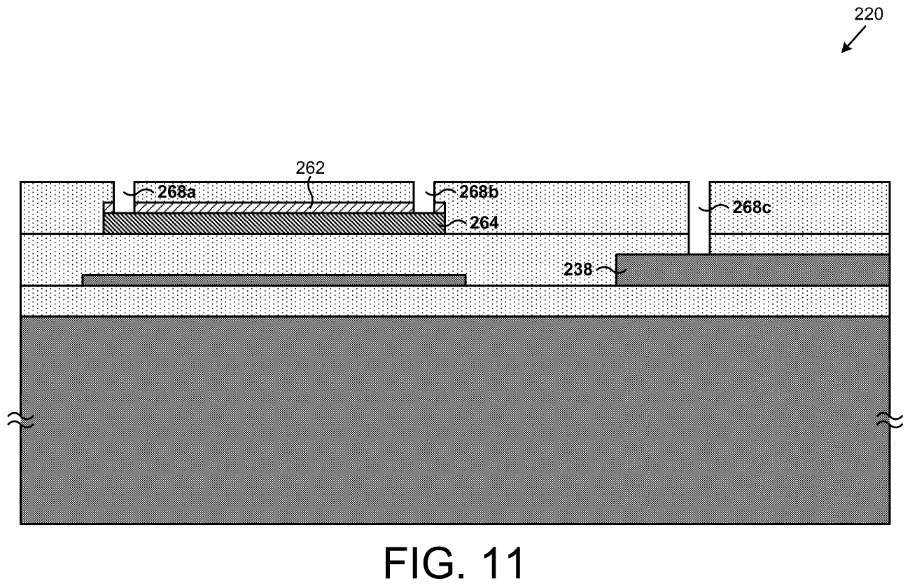

FIG. 11 illustrates a cross-sectional view of a portion of a semiconductor structure processed in accordance with action 120 in flowchart 100B of FIG. 1B according to one implementation of the present application. As shown in FIG. 11, in semiconductor structure 220, contact holes 268a and 268b are extended through capping dielectric segment 262.

Contact holes 268a and 268b expose portions of TaN resistive heater 264 for electrical connection. Contact holes 268a and 268b can be extended through capping dielectric segment 262 by etching using any technique known in the art. In one implementation, the etch is selective to capping dielectric segment 262 and stops on TaN resistive heater 264. Thus, capping dielectric segment 262 which performed as a hardmask when forming TaN resistive heater 264 in FIG. 8A can also perform as an etch stop layer when forming contact holes 268a and 268b to TaN resistive heater 264 in FIGS. 10 and 11. Where an etch stop layer (not shown) is situated over device 238, contact hole 268c may be concurrently extended through such etch stop layer to expose device 238 for electrical connection.

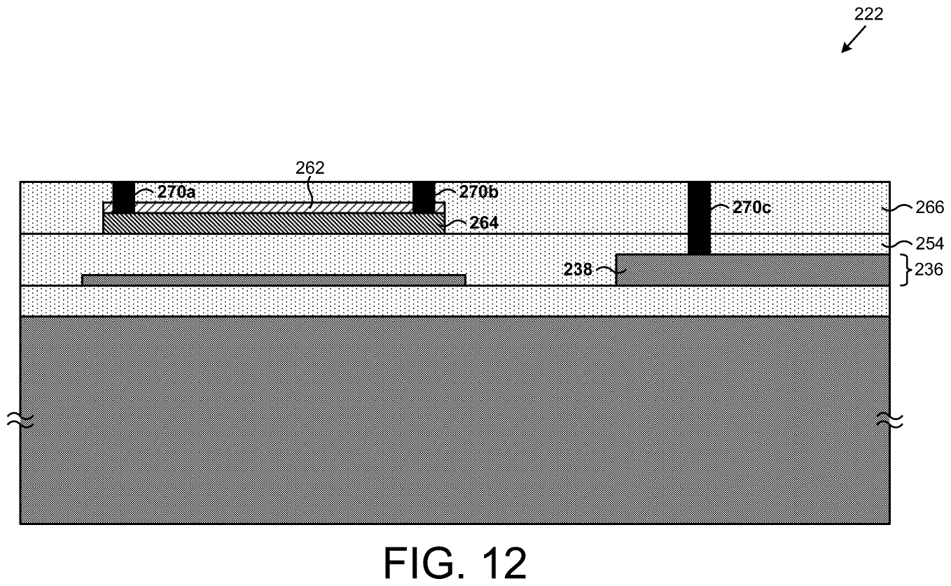

FIG. 12 illustrates a cross-sectional view of a portion of a semiconductor structure processed in accordance with action 122 in flowchart 100B of FIG. 1B according to one implementation of the present application. As shown in FIG. 12, in semiconductor structure 222, contacts 270a and 270b to TaN resistive heater 264 are formed in respective contact holes 268a and 268b (shown in FIG. 11). Likewise contact 270c to device 238 is formed in contact hole 268c (shown in FIG. 11).

Contacts 270a and 270b are situated in PMD 266 and capping dielectric segment 262 over TaN resistive heater 264. Contacts 270c is situated in PMDs 254 and 266 over device 238 in semiconductor layer 236. In one implementation, a metal is deposited in contact holes 268a, 268b, and 268c, and then planarized with PMD 266, for example, using CMP, thereby forming contacts 270a, 270b, and 270c. In an alternative implementation, a damascene process is used to form contacts 270a, 270b, and 270c. In various implementations, contacts 270a, 270b, and 270c can comprise tungsten (W), copper (Cu), or aluminum (Al).

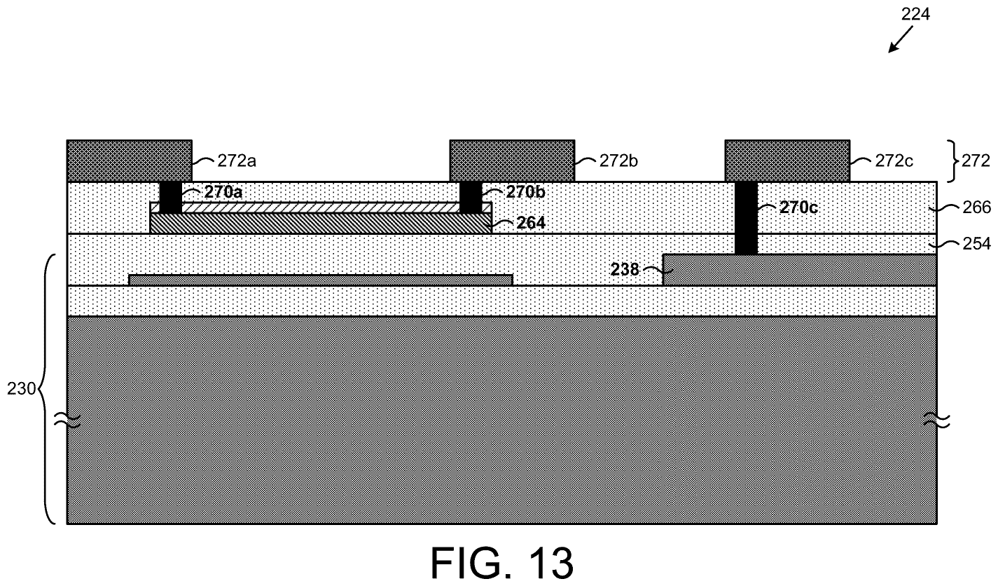

FIG. 13 illustrates a cross-sectional view of a portion of a semiconductor structure processed in accordance with action 124 in flowchart 100B of FIG. 1B according to one implementation of the present application. As shown in FIG. 13, in semiconductor structure 224, interconnect metal segments 272a, 272b, and 272c are formed over contacts 270a, 270b, and 270c.

Interconnect metal layer 272 is provided over PMD 266. Interconnect metal layer 272 includes interconnect metal segments 272a, 272b, and 272c electrically coupled to contacts 270a, 270b, and 270c respectively. In one implementation, a metal layer is deposited over PMD 266 and contacts 270a, 270b, and 270c, and then segments thereof are etched, thereby forming interconnect metal segments 272a, 272b, and 272c. In an alternative implementation, a damascene process is used to form interconnect metal segments 272a, 272b, and 272c. In various implementations, interconnect metal segments 272a, 272b, and 272c can comprise W, Al, or Cu.

Contacts 270a and 270b and interconnect metal segments 272a and 272b together route electricity to/from TaN resistive heater 264. Likewise contact 270c and interconnect metal segment 272c together route electricity to/from device 238, which can be, for example, a transistor. Although contacts 270a, 270b, and 270c and interconnect metal segments 272a, 272b, and 272c are illustrated as separate formations in FIG. 13, in other implementations they may be parts of the same formation. Semiconductor structure 224 can include other contacts and other interconnect metal segments not shown in FIG. 13.

It is noted that TaN resistive heater 264 is formed over PMD 254 in PMD 266 at a level where conventionally no metal interconnect exists. As shown in FIG. 13, TaN resistive heater 264 is not situated at the same level as interconnect metal layer 272 (i.e., is not situated at M1). TaN layer 256 (shown in FIG. 5) utilized to form TaN resistive heater 264 can be formed in a dedicated step, where a metal interconnect is not also formed from the same layer. TaN resistive heater 264 is situated between substrate 230 and the first interconnect metal level.

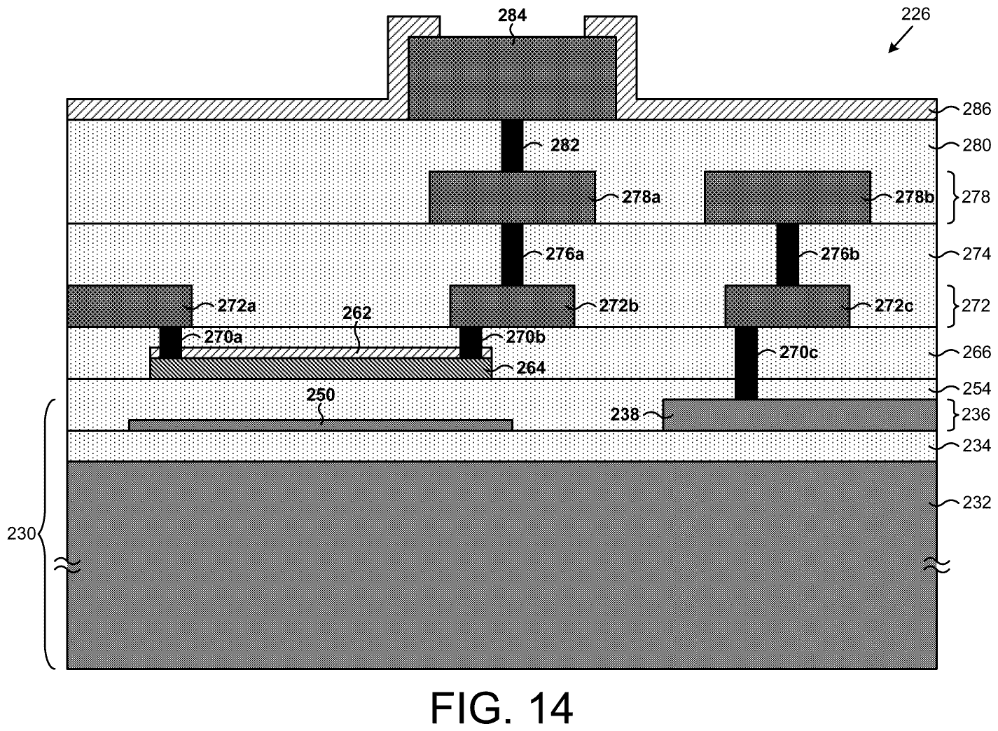

FIG. 14 illustrates a cross-sectional view of a portion of a semiconductor structure processed in accordance with action 126 in flowchart 100B of FIG. 1B according to one implementation of the present application. As shown in FIG. 14, in semiconductor structure 226, additional processing is completed. The additional processing includes forming inter-metal dielectric (IMD) 274, vias 276a and 276b, interconnect metal layer 278, interconnect metal segments 278a and 278b, IMD 280, via 282, interconnect metal segments 284, and passivation layer 286.

IMD 274 is formed over interconnect metal layer 272. Vias 276a and 276b are situated in IMD 274. Via 276a connects interconnect metal segment 272b in interconnect metal layer 272 to interconnect metal segment 278a in interconnect metal layer 278. Likewise, via 276b connects interconnect metal segment 272c in interconnect metal layer 272 to interconnect metal segment 278b in interconnect metal layer 278.

Interconnect metal layer 278 is formed over IMD 274. Interconnect metal layer 278 includes interconnect metal segments 278a and 278b electrically coupled to vias 276a and 276b respectively. Interconnect metal segments 278a and 278b are situated in and under IMD 280. Via 282 situated in IMD 280. Via 282 connects interconnect metal segment 278a in interconnect metal layer 278 to interconnect metal segment 284.

IMDs 274 and 280 can be formed in a similar manner to PMDs 254 and 266, as described above. Vias 276a, 276b, and 282 can be formed in a similar manner to contacts 270a, 270b, and 270c, as described above. Interconnect metal segments 278a, 278b, and 284 can be formed in a similar manner to interconnect metal segments 272a, 272b, and 272c, as described above.

Passivation layer 286 is formed over and on sidewalls of interconnect metal segments 284, and over IMD 280. Passivation layer 286 can be formed by conformal deposition, for example, by PVD or CVD techniques. In various implementations, passivation layer 286 can include a semiconductor-based dielectric such as Si_{X}O_{Y}, Si_{X}N_{Y}, or Si_{X}O_{Y}N_{Z}. In various implementations, passivation layer 286 can have a thickness of approximately fifty angstroms (50 Å) to approximately two hundred angstroms (200 Å). In various implementations, passivation layer 286 comprises multiple passivation layers. As shown in FIG. 14, windows are formed in passivation layer 286 exposing portions of interconnect metal segment 284. Thus, the exposed portions of interconnect metal segment 284 can function as a bond pad for electrical connections external to TaN resistive heater 264.

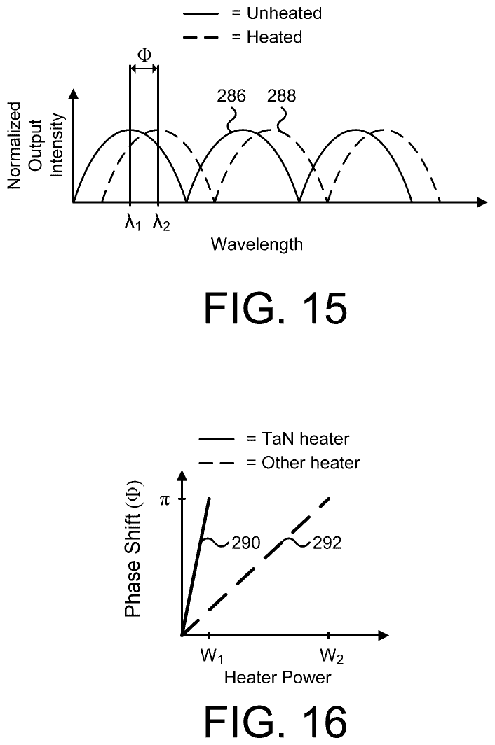

FIG. 15 illustrates an exemplary graph of output intensity versus wavelength according to one implementation of the present application. The intensity-wavelength graph in FIG. 15 represents the normalized intensity of light output by a thermally-tunable photonics device, such as at output combiner 252 of thermally-tunable Mach-Zender interferometer 244 in FIG. 8B, plotted over wavelength. Accordingly, the graph in FIG. 15 is described below with reference to semiconductor structure 214B in FIG. 8B.

Light input to input splitter 246 of thermally-tunable Mach-Zender interferometer 244 can have a wide band. Thermally-tunable Mach-Zender interferometer 244 can effectively filter the light, changing the intensity of the light to have narrow bands. As shown by trace 286 in FIG. 15, light output by thermally-tunable Mach-Zender interferometer 244 can have narrow bands. In trace 286, a peak intensity of an exemplary narrow band is shown to occur as wavelength λ₁.

The peak at wavelength λ₁ might be off from a desired wavelength for a given application, for example, due to normal process variations. When TaN resistive heater 264 is supplied with power and generates heat, the thermo-optical effect increases the refractive index of arm 250 of thermally-tunable Mach-Zender interferometer 244. In turn, thermally-tunable Mach-Zender interferometer 244 changes the intensity in a different manner. As shown by trace 288 in FIG. 15, light output by thermally-tunable Mach-Zender interferometer 244 when TaN resistive heater 264 is supplied with power can have narrow bands at different peaks compared to when TaN resistive heater 264 is not supplied with power. In trace 286, a peak intensity of an exemplary narrow band is now shown to occur as wavelength λ₂. Phase shift Φ represents the difference between wavelength λ₁ and wavelength λ₂. As described below, the magnitude of phase shift Φ generally corresponds to the power supplied to TaN resistive heater 264. Thus, TaN resistive heater 264 can shift output light band peaks (or troughs) to a desired wavelength for a given application. As a result, the output light may be processed more easily, for example, by modulators and/or encoders (not shown).

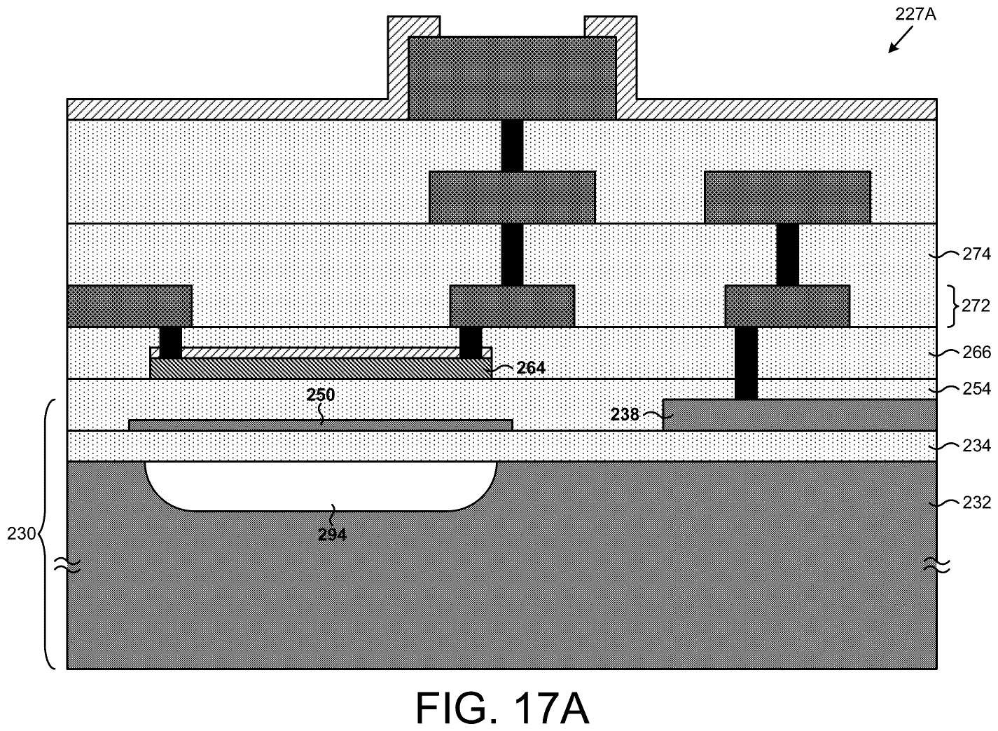

FIG. 16 illustrates an exemplary graph of phase shift versus heater power according to one implementation of the present application. The shift-power graph in FIG. 16 represents the magnitude of phase shift Φ provided by a thermally-tunable photonics device, such as at output combiner 252 of thermally-tunable Mach-Zender interferometer 244 in FIG. 8B, plotted over the power provided to a heating element, such as at TaN resistive heater 264 in FIG. 8B, situated near the thermally-tunable photonics device. Accordingly, the graph in FIG. 16 is described below with reference to semiconductor structure 214B in FIG. 8B.

Trace 290 represents the phase shift Φ versus heater power in semiconductor structure 214B that includes TaN resistive heater 264. Trace 292 represents the phase shift Φ versus heater power in another semiconductor structure that does not include TaN resistive heater 264. As shown by traces 290 and 292, the magnitude of phase shift Φ generally corresponds to the power supplied to the heating element. In various implementations, traces 290 and 292 may exhibit relationships other than those shown in FIG. 16, such as different or non-linear slopes.

However, the semiconductor structure that does not include TaN resistive heater 264 requires more power to achieve the same phase shift Φ as semiconductor structure 214B that includes TaN resistive heater 264. As shown by trace 290, semiconductor structure 214B achieves phase shift Φ of π using a heater power of W₁. In contrast, as shown by trace 292, the semiconductor structure that does not include TaN resistive heater 264 achieves phase shift Φ of π using a significantly higher heater power of W₂. Semiconductor structure 214B requires less power because TaN resistive heater 264 has a relatively low temperature coefficient and experiences less change in resistance, such that a driving circuit will need to supply less power to maintain TaN resistive heater 264 at a constant temperature.

In one implementation, a feedback system (not fully shown) which device 238 may be part of, can be coupled to output combiner 252 to dynamically control the power supplied to TaN resistive heater 264. For example, if phase shift Φ drops below a desired amount, for example, due to environmental changes, the feedback system can automatically increase the heater power.

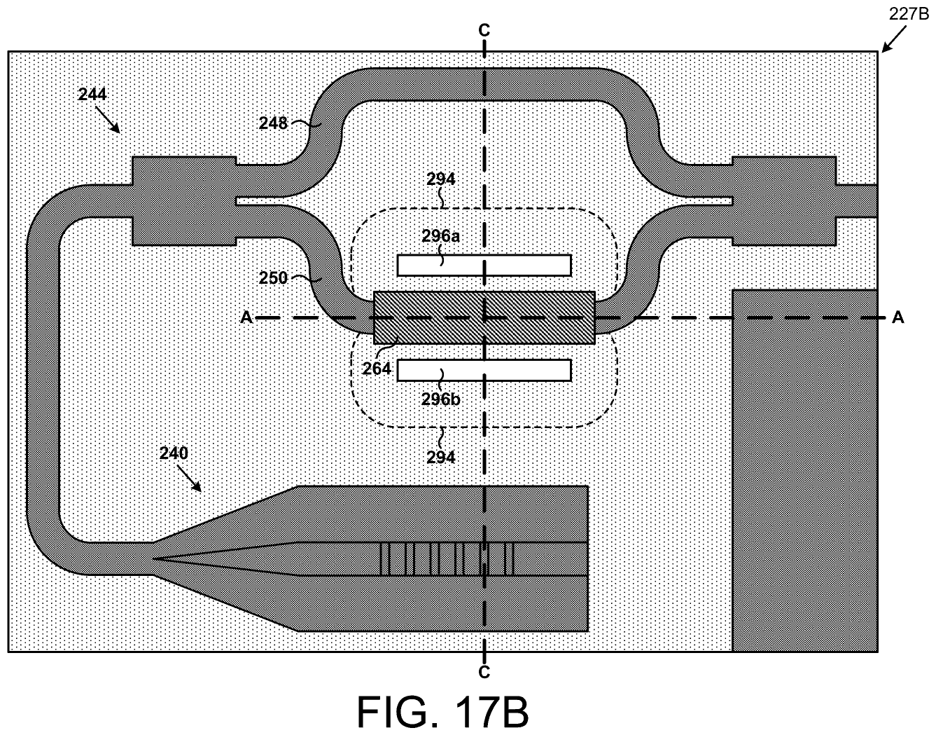

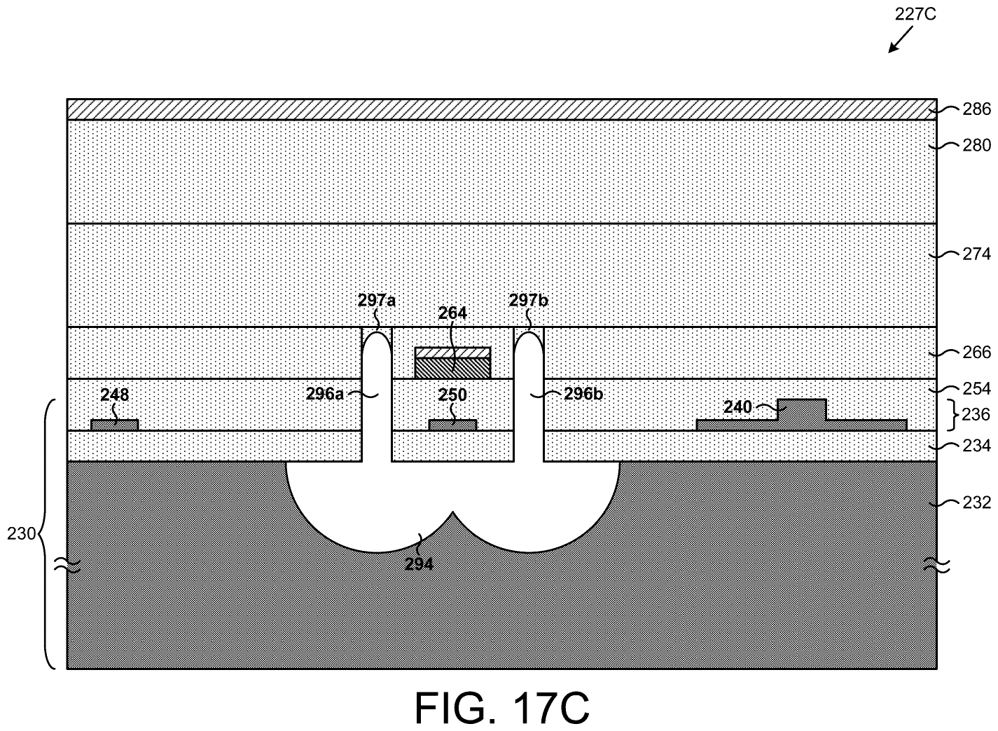

FIG. 17A illustrates a cross-sectional view of a portion of a semiconductor structure according to an alternative implementation of the present application. Semiconductor structure 227A in FIG. 17A represents an alternative to semiconductor structure 226 in FIG. 14. Except for differences noted below, semiconductor structure 227A in FIG. 17A can have any implementations and advantages described with respect to semiconductor structure 226 in FIG. 14.

As shown in FIG. 17A, cavity 294 is formed in substrate 230 underlying TaN resistive heater 264 and thermally-tunable photonics device 250. Cavity 294 is situated in handle wafer 232 of substrate 230 under BOX 234. In the present implementation, cavity 294 is filled with air. In various implementations, cavity 294 can be filled with a material other than air. Because cavity 294 has lower thermal conductivity compared to handle wafer 232, the effective thermal conductivity of substrate 230 is reduced. Less heat dissipates from TaN resistive heater 264 to substrate 230, and TaN resistive heater 264 requires less power to achieve a desired change in thermally-tunable photonics device 250.

In the present implementation, cavity 294 is also situated under and reduces heat dissipation from thermally-tunable photonics device 250. In various implementations, more or less of a thermally-tunable photonics device can be situated over cavity 294. In the present implementation, TaN resistive heater 264 and cavity 294 are not situated in proximity to device 238, to prevent overheating of device 238.

FIG. 17B illustrates a layout of a portion of a semiconductor structure corresponding to FIG. 17A according to an alternative implementation of the present application. FIG. 17A represents an exemplary cross-section along line “A” in FIG. 17B. The layout in represents a plan view at the level of TaN resistive heater 264 with various elements being seen through.

As shown in FIG. 17B, in semiconductor structure 227B, venting holes 296a and 296b are utilized to form cavity 294 in substrate 230 (shown in FIG. 17A) in proximity to TaN resistive heater 264. Cavity 294 is also situated under TaN resistive heater 264 and arm 250 of photonics device 244. Cavity 294 is illustrated with dashed lines corresponding to its approximate boundaries under BOX 234. In the present implementation, cavity 294 is not situated in proximity to photonics device 240 or arm 248, to prevent overheating.

FIG. 17C illustrates a cross-sectional view of a portion of a semiconductor structure corresponding to FIG. 17B according to an alternative implementation of the present application. FIG. 17C represents an exemplary cross-section along line “C” in FIG. 17B. As shown in FIG. 17C, in semiconductor structure 227C, venting holes 296a and 296b are formed in proximity of and on either side of TaN resistive heater 264 and arm 250.

Venting holes 296a and 296b extend through PMDs 254 and 266, and through BOX 234 in substrate 230, to handle wafer 232. Venting holes 296a and 296b can be formed, for example, using a fluorine-based anisotropic etch. Venting holes 296a and 296b can be formed using an etch that is selective to handle wafer 232 and/or using a timed etch that is not selective to handle wafer 232. Venting holes 296a and 296b are formed in proximity of TaN resistive heater 264 such that cavity 294 formed in a subsequent action would significantly reduce heat dissipation from TaN resistive heater 264 to substrate 230. In one implementation, the proximity of venting holes 296a and 296b and TaN resistive heater 264 is determined based on a process parameter of the etching action. For example, where the accuracy of the etching action can only form sidewalls of venting holes 296a and 296b within five hundred nanometers (500 nm), the proximity of venting holes 296a and 296b and TaN resistive heater 264 can be greater than or approximately five hundred nanometers (500 nm), or a multiple thereof, to ensure that TaN resistive heater 264 is not damaged in the etching action. In one implementation, of venting holes 296a and 296b can be situated closer to TaN resistive heater 264 than all other devices in semiconductor structure 227C. In various implementations, semiconductor structure 227C can include more or fewer venting holes.

Cavity 294 is situated in handle wafer 232 of substrate 230 and contiguous with venting holes 296a and 296b. An isotropic dry plasma etch, for example, using sulfur hexafluoride (SF₆), through venting holes 296a and 296b can be utilized to form cavity 294. Cavity 294 can be formed using an etch that is selective to handle wafer 232 such that BOX 234 remains substantially unetched. Notably, cavity 294 is not etched to the backside of substrate 230, to avoid cracking and/or mechanical instability.

After forming cavity 294, venting holes 296a and 296b can be sealed, for example, by depositing a dielectric using a non-conformal low gap-fill process, such as CVD, that causes the dielectric to pinch-off venting holes 296a and 296b near the tops of venting hole holes 296a and 296b. The deposited dielectric can then be planarized with PMD, as shown in FIG. 17C, resulting in pinched-off regions 297a and 297b. Alternatively, pinched-off regions 297a and 297b may be formed from the same deposition used for

IMD 274. In various implementations, venting holes 296a and 296b can be formed at different manufacturing stages and extend through different layers. For example, venting holes 296a and 296b can be formed after IMD 280 and before passivation layer 286, and can extend through IMDs 274 and 280.

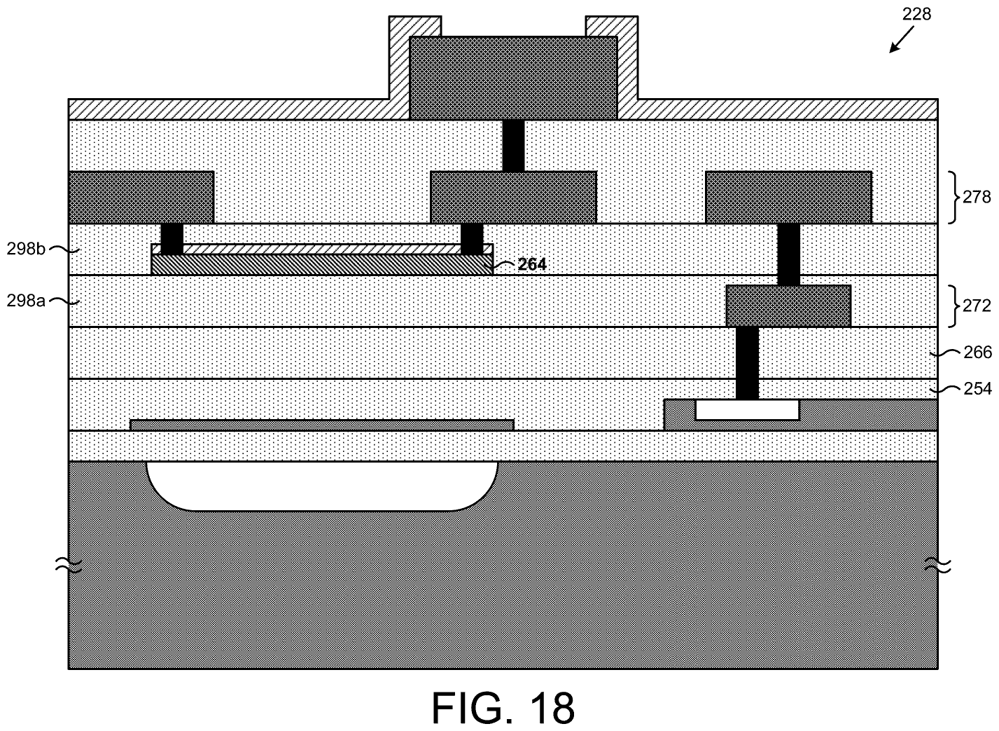

FIG. 18 illustrates a cross-sectional view of a portion of a semiconductor structure according to an alternative implementation of the present application. Semiconductor structure 228 in FIG. 18 represents an alternative to semiconductor structure 227A in FIG. 17A. Except for differences noted below, semiconductor structure 228 in FIG. 18 can have any implementations and advantages described with respect to semiconductor structure 227A in FIG. 17.

In FIG. 17A, TaN resistive heater 264 is between substrate 230 and interconnect metal layer 272, in PMD 266 and on PMD 254. In contrast, in FIG. 18, TaN resistive heater 264 is between interconnect metal layer 272 and interconnect metal layer 278 (i.e., is situated between two consecutive metal levels at a level where conventionally no metal interconnect exists). Instead of IMD 274 in FIG. 17, two thinner IMDs 298a and 298b are utilized in FIG. 18. TaN resistive heater 264 is in IMD 298b on IMD 298a. In various implementations, the thicknesses and materials of IMD 298a and PMDs 254 and 266 can be chosen to facilitate TaN resistive heater 264 tuning thermally-tunable photonics device 250.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A semiconductor structure comprising:
a substrate;
a thermally-tunable photonics device in said substrate;
a tantalum nitride (TaN) resistive heater over said substrate, said TaN resistive heater proximate to and configured to tune said thermally-tunable photonics device;
a capping dielectric segment over and substantially aligned with said TaN resistive heater.

2. The semiconductor structure of claim 1, wherein said TaN resistive heater overlies said thermally-tunable photonics device.

3. The semiconductor structure of claim 1, wherein said thermally-tunable photonics device comprises an interferometer, a phase shifter, a waveguide, or an optical switch.

4. The semiconductor structure of claim 1, wherein said TaN resistive heater is situated between said substrate and a first interconnect metal level.

5. The semiconductor structure of claim 1, wherein said TaN resistive heater is situated between two consecutive interconnect metal levels.

6. The semiconductor structure of claim 1, further comprising:
a pre-metal dielectric (PMD) or an inter-metal dielectric (IMD) over said capping dielectric segment;
a contact to said TaN resistive heater situated in said PMD or said IMD and in said capping dielectric segment.

7. The semiconductor structure of claim 1, wherein said capping dielectric segment comprises silicon nitride.

8. The semiconductor structure of claim 1, further comprising a cavity in said substrate underlying said TaN resistive heater.

9. The semiconductor structure of claim 8, wherein:
said substrate is a semiconductor-on-insulator (SOI) substrate;
said cavity is situated in a handle wafer of said SOI substrate.

10. A semiconductor structure comprising:
a substrate;
a waveguide comprising a photonics material selected from the group consisting of silicon, silicon nitride, and a Pockels material;
a tantalum nitride (TaN) resistive heater over said waveguide;
a capping dielectric segment over and substantially aligned with said TaN resistive heater.

11. The semiconductor structure of claim 10, wherein said photonics material comprises said Pockels material selected from the group consisting of lithium niobate (LiNbO₃), lithium tantalate (LiTa), potassium dihydrogen phosphate (KDP), deuterated potassium dihydrogen phosphate (DKDP), rubidium titanyl phosphate (RTP), potassium titanyl phosphate (KTP), potassium titanyl arsenate (KTA), barium borate (BBO), barium titanate (BTO), ammonium dihydrogen phosphate (ADP), and cadmium telluride (CdTe).

12. The semiconductor structure of claim 10, wherein said capping dielectric segment comprises silicon nitride.

13. The semiconductor structure of claim 10, further comprising a cavity in said substrate underlying said TaN resistive heater.

14. The semiconductor structure of claim 13, wherein:
said substrate is a semiconductor-on-insulator (SOI) substrate;
said cavity is situated in a handle wafer of said SOI substrate.

15. A method comprising:
providing a substrate;
forming a thermally-tunable photonics device;
forming a tantalum nitride (TaN) layer over said substrate;
forming a capping dielectric layer over said TaN layer;
etching said capping dielectric layer to form a capping dielectric segment;
forming a TaN resistive heater from said TaN layer, said TaN resistive heater proximate to and configured to tune said thermally-tunable photonics device.

16. The method of claim 15, wherein said TaN resistive heater overlies said thermally-tunable photonics device.

17. The method of claim 15, wherein said thermally-tunable photonics device comprises an interferometer, a phase shifter, a waveguide, or an optical switch.

18. The method of claim 15, further comprising:
forming a pre-metal dielectric (PMD) or an inter-metal dielectric (IMD) over said capping dielectric segment;
forming a contact hole in said PMD or said IMD over said TaN resistive heater;
extending said contact hole through said capping dielectric segment.

19. The method of claim 19, wherein said capping dielectric segment comprises silicon nitride.

20. The method of claim 19, further comprising forming a cavity in said substrate underlying said TaN resistive heater.39
